(19) United States
(12) Patent Application Publication
(10) Pub. No.: US 2026/0150351 A1
(43) Pub. Date: May 28, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Yan-Chun Liu, Taichung City (TW); Shih-Chieh Chang, Taipei City (TW); Sheng-Syun Wong, Hsinchu County (TW)

(73) Assignee: Taiwan Semiconductor Manufacturing Company, Ltd., Hsinchu (TW)

(21) Appl. No.: 18/961,955

(22) Filed: Nov. 27, 2024

(51) Int. Cl. H01L 29/06; H01L 21/02; H01L 29/417; H01L 29/423; H01L 29/66; H01L 29/775; H01L 29/786

(52) U.S. Cl. CPC H10D 62/116; H10D 64/021; H10D 64/258; H10P 14/6927; H10D 30/43; H10D 30/6735; H10D 30/6757; H10D 62/121

(57) ABSTRACT

A fabrication method, includes: forming a recess in an epitaxial stack including alternating sacrificial epitaxial layers and channel epitaxial layers through removing sacrificial epitaxial layer material; forming a first inner spacer layer including silicon boride (SiB) in the recess adjacent to the sacrificial epitaxial layer material; forming a second inner spacer layer including silicon oxycarbonitride (SiOCN) in the recess adjacent to the first inner spacer layer; forming a source/drain feature adjacent to the second inner spacer layer; and replacing the sacrificial epitaxial layer material with a metal gate layer, wherein the first inner spacer layer reduces inner spacer loss while the sacrificial epitaxial layer material is replaced with the metal gate layer.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart depicting an example method 100 of semiconductor fabrication including fabrication of multi-gate devices, in accordance with some embodiments.

FIGS. 2-3, 4A-4C, 5, 6A-6B, and 7-17, are schematic diagrams of a semiconductor structure at various stages of fabrication, in accordance with some embodiments.

FIGS. 18A-18D are schematic diagrams depicting example double inner spacer layer configurations, in accordance with some embodiments.

FIG. 19 is a flowchart of an example method for forming a double inner spacer layer in a transistor device, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

It should be understood that, although the terms first, second, third etc. may be used herein to describe various elements, components, regions, layers, portions and/or sections, these elements, components, regions, layers, portions, and/or sections should not be limited by these terms. These terms are only used to distinguish one element, component, region, layer, portion or section from another region, layer, or section. Thus, a first element, component, region, layer, portion, or section discussed below could be termed a second element, component, region, layer, portion, or section without departing from the teachings of the present disclosure.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

In certain embodiments herein, a “material layer” is a layer that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a layer that is a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of an aluminum layer and a layer of aluminum is a layer that is at least 50 wt. %, at least 60 wt. %, at least 75 wt. %, at least 90 wt. %, at least 95 wt. %, or at least 99 wt. % of aluminum.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

While the figures illustrate various embodiments of a semiconductor device, additional features may be added in the semiconductor device depicted in the Figures and some of the features described below can be replaced, modified, or eliminated in other embodiments of the semiconductor device.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

The present disclosure is generally related to semiconductor devices and the fabrication thereof, and in some cases to multi-gate devices. Multi-gate devices include those transistors whose gate structures are formed on at least two-sides of a channel region. These multi-gate devices may include an n-type metal-oxide-semiconductor device or a p-type metal-oxide-semiconductor multi-gate device. Specific examples herein may be presented and referred to herein as a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Presented herein are embodiments of devices that may have one or more channel regions (e.g., nanosheets) associated with a single, contiguous gate structure. One of ordinary skill may recognize other examples of semiconductor devices that may benefit from aspects of the present disclosure.

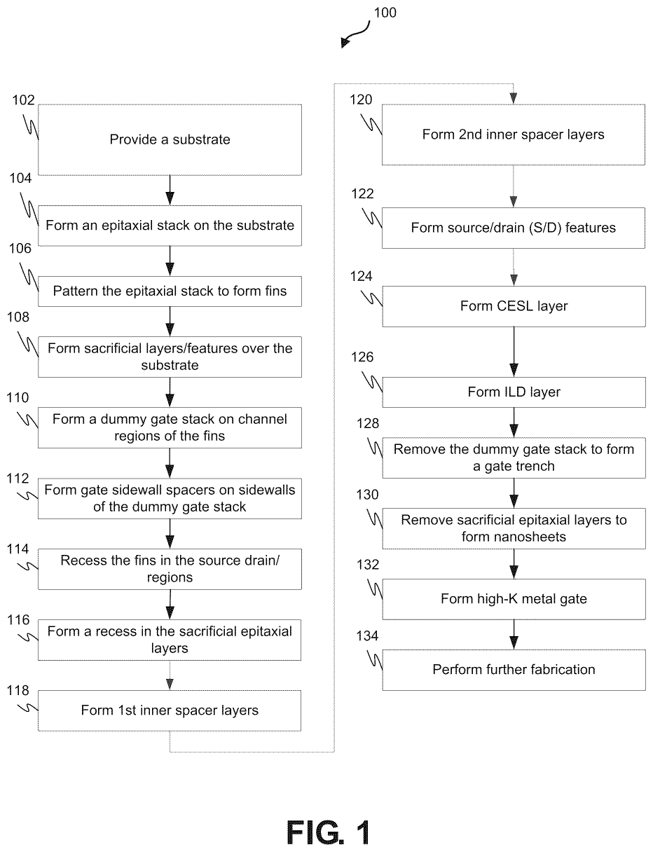

FIG. 1 is a flow chart depicting an example method 100 of semiconductor fabrication including fabrication of multi-gate devices, according to various aspects of the present disclosure. As used herein, the term “multi-gate device” is used to describe a device (e.g., a semiconductor transistor) that has at least some gate material disposed on multiple sides of at least one channel of the device. In some examples, the multi-gate device may be referred to as a GAA device having gate material disposed on four sides of at least one channel member of the device. The channel member may be referred to as “nano structure” or “nanosheet,” which is used herein to designate any material portion with nanoscale, or even microscale dimensions, and having an elongate shape, regardless of the cross-sectional shape of this portion. Thus, the term “nanostructure” or “nanosheet” as used herein designates both circular and substantially circular cross-section elongate material portions, and beam or bar-shaped material portions including for example a cylindrical in shape or substantially rectangular cross-section.

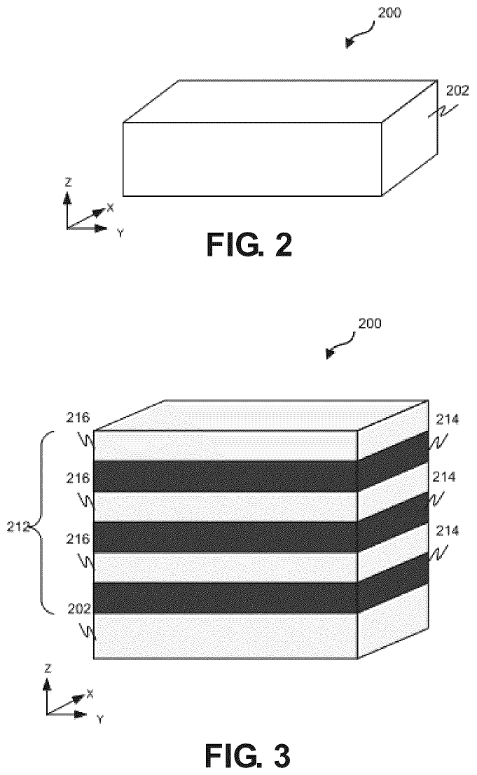

FIG. 1 is described in conjunction with FIGS. 2-3, 4A-4C, 5, 6A-6B, and 7-17, which illustrate a semiconductor device 200 or structure at various stages of fabrication in accordance with some embodiments. The method 100 is merely an example and is not intended to limit the present disclosure beyond what is explicitly recited in the claims. Additional steps may be provided before, during, and after method 100, and some of the steps described can be moved, replaced, or eliminated for additional embodiments of method 100. Additional features may be added in the semiconductor device 200 depicted in the figures, and some of the features described below can be replaced, modified, or eliminated in other embodiments.

As with the other method embodiments and exemplary devices discussed herein, it is understood that parts of the semiconductor devices may be fabricated by semiconductor technology process flow, and thus some processes are only briefly described herein. Further, the exemplary semiconductor devices may include various other devices and features, such as other types of devices such as additional transistors, bipolar junction transistors, resistors, capacitors, inductors, dials, fuses, and/or other logic devices, etc., but is simplified for better understanding of concepts of the present disclosure. In some embodiments, exemplary devices include a plurality of semiconductor devices (e.g., transistors), including PFETs, NFETs, etc., which may be interconnected. Moreover, it is noted that the process steps of method 100, include any descriptions given with reference to the figures, as with the remainder of the method and exemplary figures provided in this disclosure, are merely exemplary and are not intended to be limiting beyond what is specifically recited in the claims that follow.

FIGS. 2-3, 4A-4C, 5, 6A-6B, and 7-17, are schematic diagrams that illustrate an example semiconductor device structure at various stages of fabrication, in accordance with some embodiments. In some figures, some reference numbers of components or features illustrated therein may be omitted to avoid obscuring other components or features; this is for ease of depicting the figures.

At block 102, the example method 100 includes providing a substrate. Referring to the example of FIG. 2, in an embodiment of block 102, a substrate 202 is provided for forming a transistor device 200. In some embodiments, the substrate 202 may be a semiconductor substrate such as a silicon (Si) substrate. In some embodiments, the substrate 202 includes a single crystalline semiconductor layer on at least its surface portion. The substrate 202 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 202 may include a compound semiconductor and/or an alloy semiconductor. The substrate 202 may include various layers, including conductive or insulating layers formed on a semiconductor substrate. The substrate 202 may include various doping configurations depending on design requirements. For example, different doping profiles (e.g., n wells, p wells) may be formed on the substrate 202 in regions designed for different device types (e.g., n-type field effect transistors (NFET), p-type field effect transistors (PFET)). The suitable doping may include ion implantation of dopants and/or diffusion processes. The substrate 202 has isolation features (e.g., shallow trench isolation (STI) features) interposing the regions providing different device types. Further, the substrate 202 may be strained for performance enhancement, may include a silicon-on-insulator (SOI) structure, and/or have other suitable enhancement features.

At block 104, the example method 100 then includes forming an epitaxial stack over the substrate that includes a plurality of epitaxial layers. Referring to the example of FIG. 3, in an embodiment of block 104, an epitaxial stack 212 is formed over the substrate 202. The epitaxial stack 212 includes sacrificial epitaxial layers 214 of a first composition interposed by channel epitaxial layers 216 of a second composition. The first and second composition can be different. In an embodiment, the sacrificial epitaxial layers 214 are formed from SiGe and the channel epitaxial layers 216 are formed from silicon (Si). However, other embodiments are possible including those that provide for a first composition and a second composition having different oxidation rates and/or etch selectivity. In some embodiments, the sacrificial epitaxial layer 214 includes SiGe and the channel epitaxial layer 216 includes silicon (Si). However, other embodiments are possible including those that provide for a first composition and a second composition having different oxidation rates and/or etch selectivity. In some embodiments, the sacrificial epitaxial layer 214 includes SiGe and where the channel epitaxial layer 216 includes Si, the Si oxidation rate of the channel epitaxial layer 216 is less than the SiGe oxidation rate of the sacrificial epitaxial layer 214. It is noted that three (3) layers each of epitaxial layers 214 and 216 are illustrated in FIG. 3, which is for illustrative purposes only and not intended to be limiting beyond what is specifically recited in the claims. In various embodiments, any number of epitaxial layers can be formed in the epitaxial stack 212; the number of layers depending on the desired number of channel regions for the device 200. In some embodiments, the number of channel epitaxial layers 216 is between 2 and 10, such as 3, 4 or 5.

In some embodiments, the sacrificial epitaxial layer 214 has a thickness ranging from about 4 nm to about 12 nm. The sacrificial epitaxial layers 214 may be substantially uniform in thickness. In some embodiments, the channel epitaxial layer 216 has a thickness ranging from about 3 nm to about 6 nm. In some embodiments, the channel epitaxial layers 216 of the stack are substantially uniform in thickness.

As described in more detail below, the channel epitaxial layer 216 may serve as channel region(s) for a subsequently-formed multi-gate device and its thickness is chosen based on device performance considerations. The sacrificial epitaxial layer 214 may serve to reserve a spacing (or referred to as a gap) between adjacent channel region(s) for a subsequently-formed multi-gate device and its thickness is chosen based on device performance considerations.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxially grown layers, such as the channel epitaxial layers 216, include the same material as the substrate 202, such as silicon (Si). In some embodiments, the epitaxially grown layers 214 and 216 include a different material than the substrate 202. As stated above, in at least some examples, the sacrificial epitaxial layer 214 includes an epitaxially grown Si₁₋ₓGeₓ layer (e.g., x is about 25^{˜}55%) and the channel epitaxial layer 216 includes an epitaxially grown Si layer. Alternatively, in some embodiments, either of the sacrificial epitaxial layers 214 and channel epitaxial layers 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the sacrificial epitaxial layers 214 and channel epitaxial layers 216 may be chosen based on providing differing oxidation and etch selectivity properties. In various embodiments, the epitaxial layers 214 and 216 are substantially dopant-free (i.e., having an extrinsic dopant concentration from about 0 cm⁻³ to about 1×10¹⁷ cm⁻³), where for example, no intentional doping is performed during the epitaxial growth process.

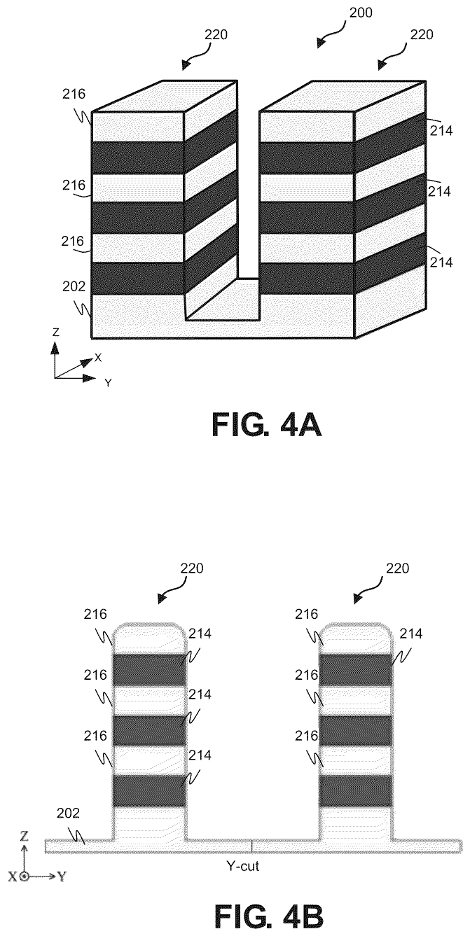

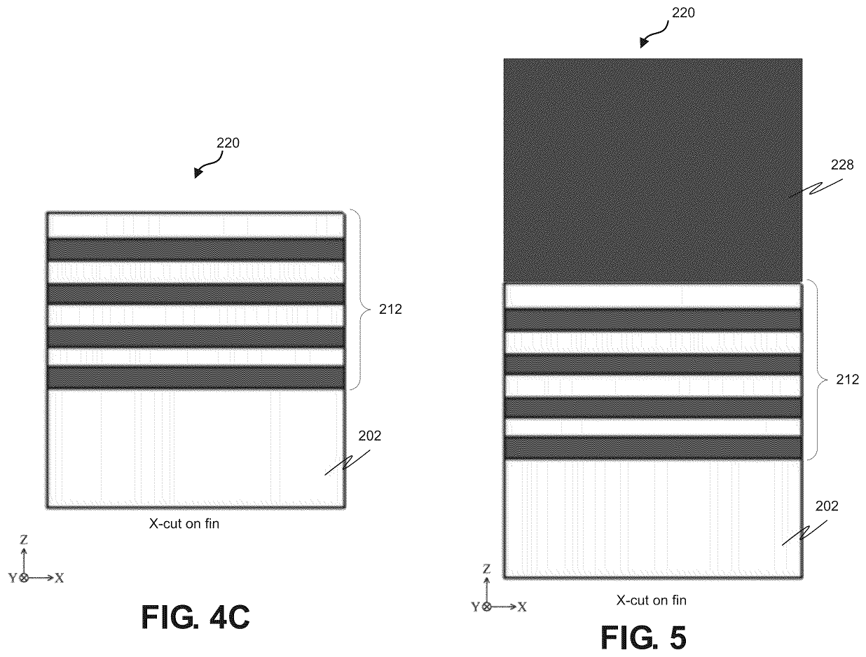

At block 106, the example method 100 includes patterning the epitaxial stack to form semiconductor fins (also referred to as fins). Referring to the example of FIGS. 4A, 4B, and 4C, in an embodiment of block 106, a plurality of fins 220 extending from the substrate 202 are formed. In various embodiments, each of the fins 220 includes an upper portion of the interleaved epitaxial layers 214 and 216 and a bottom portion protruding from the substrate 202.

The fins 220 may be fabricated using suitable processes including photolithography and etch processes. The photolithography process may include forming a photoresist layer over the substrate 202 (e.g., over the epitaxial stack 212), exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the substrate 202, and epitaxial stack 212 formed thereupon, while an etch process forms trenches in unprotected regions through masking layer(s) such as hard mask, thereby leaving the plurality of extending fins. The trenches may be etched using a dry etch (e.g., reactive ion etching), a wet etch, and/or other suitable processes. The trenches may be filled with dielectric material forming, for example, shallow trench isolation features interposing the fins.

At block 108, the example method 100 includes forming one or more sacrificial layers/features over the substrate. Referring to the example of FIG. 5, in an embodiment of block 108, a sacrificial gate dielectric layer (not shown) is blanket deposited over a stop layer 222, which is formed over the fin 220, which is formed over the substrate 202. A sacrificial gate electrode layer 228 is then blanket deposited on the sacrificial gate dielectric layer and over the substrate 202. The sacrificial gate electrode layer 228 includes silicon such as polycrystalline silicon or amorphous silicon. The thickness of the sacrificial gate dielectric layer is in a range from about 1 nm to about 5 nm in some embodiments. The thickness of the sacrificial gate electrode layer is in a range from about 100 nm to about 200 nm in some embodiments. In some embodiments, the sacrificial gate electrode layer is subjected to a planarization operation. The sacrificial gate dielectric layer and the sacrificial gate electrode layer 228 may be deposited using CVD, including LPCVD and PECVD, PVD, ALD, or other suitable processes.

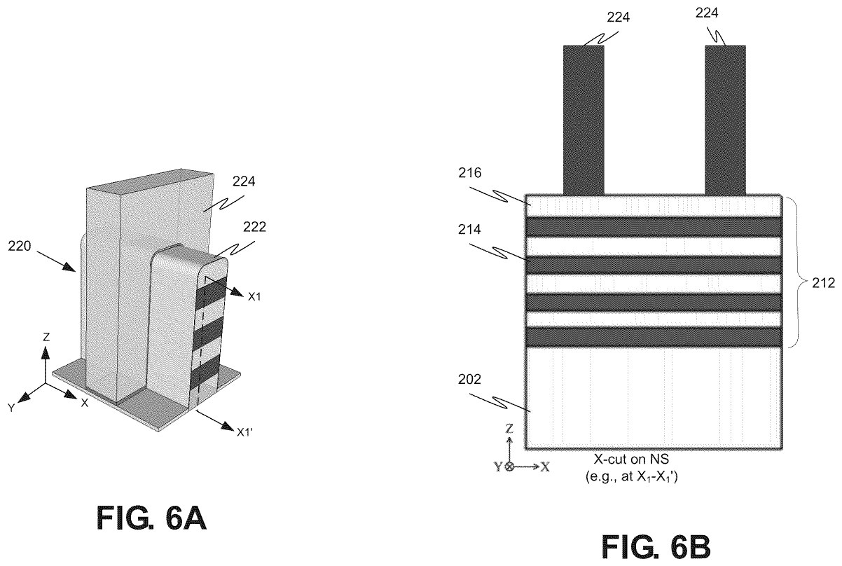

At block 110, the example method 100 includes patterning the one or more sacrificial layers/features to form a dummy gate structure on channel regions of the fins. Referring to the example of FIGS. 6A and 6B, in an embodiment of block 110, a sacrificial gate structure 224 is formed over portions of the fins 220 which are to be channel regions. The sacrificial gate structure 224 defines the channel regions of a GAA device. The sacrificial gate structure 224 includes a sacrificial gate dielectric layer and a sacrificial gate electrode layer 228. The sacrificial gate structure 224 is formed by forming a mask layer over the sacrificial gate electrode layer. The mask layer may include a pad silicon oxide layer and a silicon nitride mask layer. Subsequently, a patterning operation is performed on the mask layer and sacrificial gate dielectric and electrode layers are patterned into the sacrificial gate structure 224. By patterning the sacrificial gate structure 224, the fins 220 are partially exposed on opposite sides of the sacrificial gate structure 224, thereby defining source/drain (S/D) regions. In this disclosure, a source and a drain are interchangeably used, and the structures thereof are substantially the same.

The sacrificial gate structure 224 is subsequently removed as discussed with reference to block 132 of the method 100 and will be replaced by a final gate stack at a subsequent processing stage of the device 200. In particular, the sacrificial gate structure 224 is replaced at a later processing stage by a high-K dielectric layer (HK) and metal gate electrode (MG) as discussed below.

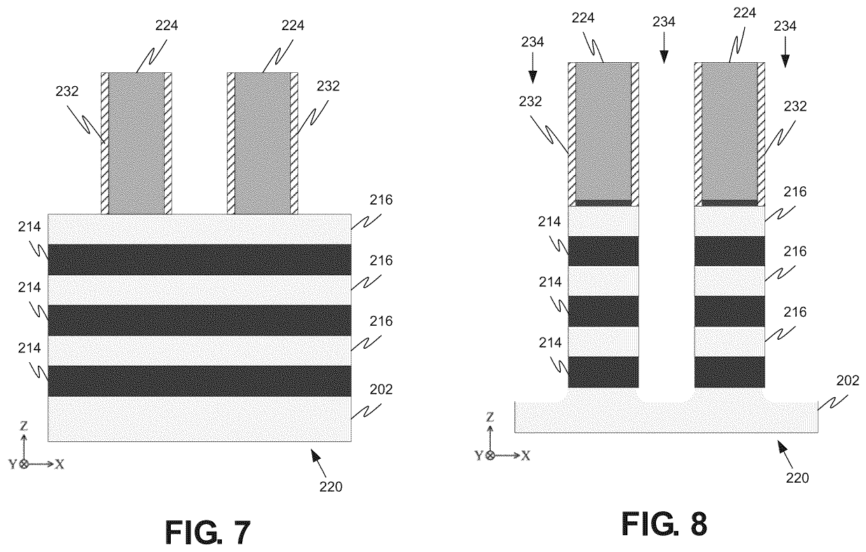

At block 112, the example method 100 includes forming gate sidewall spacers on sidewalls of the sacrificial gate structure. Referring to the example of FIG. 7, in an embodiment of block 112, gate sidewall spacers 232 are formed on sidewalls of the sacrificial gate structure 224. In various embodiments, the gate sidewall spacers 232 may include a dielectric material such as silicon oxide (SiOₓ), silicon nitride (SiN), silicon carbide (SiC), silicon oxynitride (SiON), SiCN films, silicon oxycarbide (SiOC), Silicon oxycarbonitride (SiOCN) films, and/or combinations thereof. In some embodiments, the gate sidewall spacers 232 include multiple layers, such as main spacer walls, liner layers, and the like. By way of example, the gate sidewall spacers 232 may be formed by depositing a dielectric material layer over the sacrificial gate structure 224 using processes such as, a CVD process, a sub atmospheric CVD (SACVD) process, a flowable CVD process, an ALD process, a PVD process, or other suitable process. In some embodiments, the deposition of the dielectric material layer is followed by an etching-back (e.g., anisotropically) process to expose portions of the fin 220 adjacent to and not covered by the sacrificial gate structure 224 (e.g., S/D regions). The dielectric material layer may remain on the sidewalls of the sacrificial gate structure 224 as gate sidewall spacers 232. In some embodiments, the etching-back process may include a wet etch process, a dry etch process, a multiple-step etch process, and/or a combination thereof. The gate sidewall spacers 232 may have a thickness ranging from about 5 nm to about 20 nm.

At block 114, the example method includes recessing the fins in the source drain/regions. Referring to the example of FIG. 8, in an embodiment of block 116, the fin 220 is recessed in the source drain/regions. The stacked epitaxial layers 214 and 216 are etched down at the S/D regions to form a recess 234. In various embodiments, the recessing is performed by a suitable etching process, such as a dry etching process, a wet etching process, or an RIE process. Dry etching may be implemented using an etchant including a bromine-containing gas (e.g., HBr and/or CHBR3), a fluorine-containing gas (e.g., CF4, SF6, CH2F2, CHF3, and/or C2F6), other suitable gases, or combinations thereof.

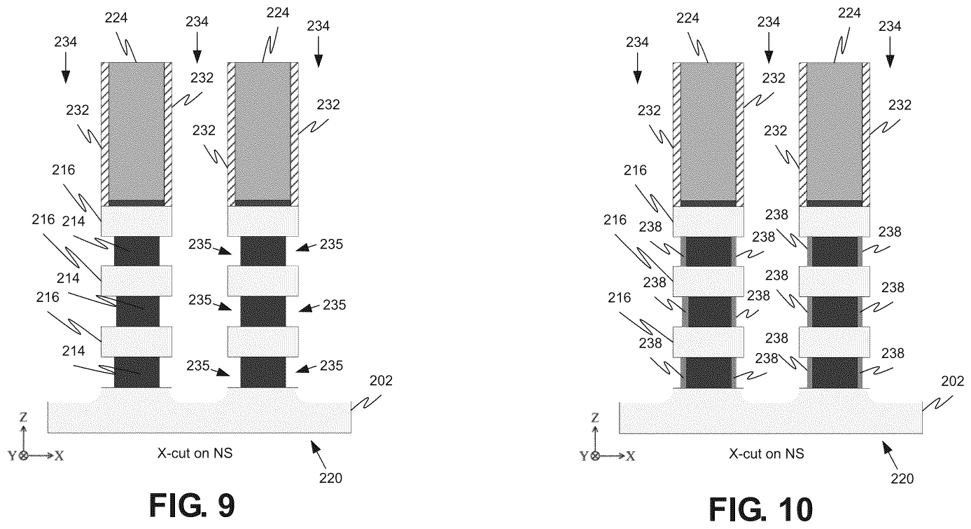

At block 116, the example method 100 includes forming a recess in the sacrificial epitaxial layers (e.g., SiGe) of the epitaxial stack. Referring to the example of FIG. 9, in an embodiment of block 116, the sacrificial epitaxial layers 214 have been etched back forming sacrificial epitaxial layer recesses 235 bounded on the top and bottom by channel epitaxial layers 216 and laterally by the recessed sacrificial epitaxial layers 214. The sacrificial epitaxial layers 214 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. Alternatively, at block 118 lateral ends of the sacrificial epitaxial layers 214 that are exposed in the recess 234 may be selectively oxidized to increase the etch selectivity between the epitaxial layers 214 and 216. In some examples, the oxidation process may be performed by exposing the device 200 to a wet oxidation process, a dry oxidation process, or a combination thereof.

At block 118, the example method 100 Includes forming a first inner spacer layer of a first material type in the sacrificial epitaxial layer recesses. Forming the first inner spacer layer may include depositing inner spacer material of the first material type in the sacrificial epitaxial layer recesses. Referring to the example of FIG. 10, in an embodiment of block 118, first inner spacer layers 238 are formed in the sacrificial epitaxial layer recesses 235. The first inner spacer layers 238 may be formed from SiB (silicon boride) and/or other suitable dielectric materials. In various embodiments, the SiB is formed using in-situ doping by B₂H₆ or BCl₃. In various embodiments, the SiB is formed using SiH₂Cl₂ or SiH₄ or Si₂H₆ as the Si resource, B₂H₆ or BCl₃ as the B resource, and HCl or Cl₂ as an etch gas. In various embodiments, during SiB deposition, an etch gas is used to reduce the SiB growth rate on the channel epitaxial layers 216 so that the SiB is deposited on the sacrificial epitaxial layers 214 but not the channel epitaxial layers 216. In various embodiments, during SiB deposition, an HCl is used as the etch gas to reduce the SiB growth rate on the channel epitaxial layers 216 so that the SiB is deposited on the sacrificial epitaxial layers 214 but not the channel epitaxial layers 216. In various embodiments, during SiB deposition, an HCl co-flow is used to reduce the SiB growth rate on the channel epitaxial layers 216 so that the SiB is deposited on the sacrificial epitaxial layers 214 but not the channel epitaxial layers 216. In various embodiments, all the gasses used in forming the SiB flow into processing chamber at the same time (co-flow). In some embodiments, the first inner spacer layers 238 is deposited as a conformal layer. The first inner spacer layers 238 can be formed by ALD or any other suitable method.

At block 119, the example method 100 includes and performing a wet clean of the deposited inner spacer material of the first material type. Performing a wet clean can remove oxide off of the surfaces of the first inner spacer layers.

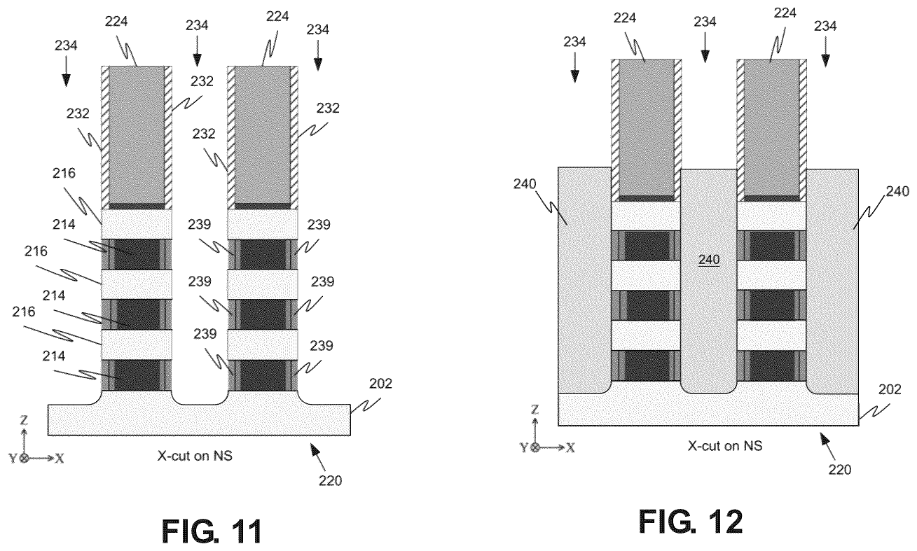

At block 120, the example method 100 includes forming a second inner spacer layer of a second material type in the sacrificial epitaxial layer recesses. Forming the second inner spacer layer may include depositing inner spacer material of the second material type, and trimming the second inner spacer layers (e.g., via etching operations). Referring to the example of FIG. 11, in an embodiment of block 120, second inner spacer layers 239 are formed in the sacrificial epitaxial layer recesses 235 adjacent to the first inner spacer layers 238. The second inner spacer layers 239 may be formed from silicon oxides, silicon nitrides, silicon carbides, silicon carbide nitride, silicon oxide carbide, silicon carbide oxynitride, and/or other suitable dielectric materials. In some embodiments, the second inner spacer layers 239 are deposited as a conformal layer. The second inner spacer layers 239 can be formed by ALD or any other suitable method. After the second inner spacer layers 239 are formed, an etching operation may be performed to partially remove the second inner spacer layers 239. In various embodiments, the second inner spacer layers 239 are formed from the same material as the gate sidewall spacers 232. In various embodiments, the gate sidewall spacers 232 and the second inner spacer layers 239 are formed from SiOCN.

Inner spacers can play a role in a GAA structure to prevent EPI damage. With a single inner spacer layer, spacer loss may occur after nanosheet formation. Inner spacer loss can induce EPI damage and results in low yield. The disclosed double layer inner spacer layers comprising the first inner spacer layers 238 and the second inner spacer layers 239 can prevent EPI damage. The first inner spacer layers 238 can reduce or prevent inner spacer loss during metal gate replacement operations and therefore prevent EPI damage.

At block 122, the example method 100 includes forming source/drain (S/D) features. Forming the S/D features may involve depositing pure silicon in the recess 234 in the source drain/regions. If recessing the fins in the source/drain regions (at block 114) did not completely etch the bottom sacrificial epitaxial layer 214, SiGe residue may exist above the substrate 202 in a source/drain region. In various embodiments, recessing the fins in the S/D regions may involve over etching the fins in the S/D regions wherein some of the substrate 202 below the height level of the bottom sacrificial epitaxial layer 214 is removed to prevent SiGe residue. Pure Si is deposited in the recess 234 to raise the height of the substrate 202 below the recess 234 to the height level of the bottom sacrificial epitaxial layer 214.

Forming the S/D features may also involve depositing mask layer material over the NMOS S/D regions and the PMOS S/D regions, patterning the PMOS S/D regions to remove the mask layer material over the PMOS S/D regions, and depositing PMOS material for forming epitaxial S/D features in the PMOS S/D regions. Following forming the epitaxial S/D features in the PMOS S/D regions, forming the S/D features may involve depositing mask layer material over the PMOS S/D regions, patterning the NMOS S/D regions to remove the mask layer material over the NMOS S/D regions, and depositing NMOS material for forming epitaxial S/D features in the NMOS S/D regions. In various embodiments, the mask layer material comprises AlOx. In some embodiments, the mask layer material may comprise some other type of material such as SiN. The mask layer material is used during PMOS S/D feature formation to prevent depositing PMOS epitaxial material in the NMOS area. The mask layer material is used during NMOS S/D feature formation to prevent depositing NMOS epitaxial material in the PMOS area.

Referring to the example of FIG. 12, in an embodiment of block 122, epitaxial S/D features 240 are formed in recess 234. In some embodiments, the epitaxial S/D features 240 include silicon for NFETs and SiGe for PFETs. In some embodiments, the epitaxial S/D features 240 are formed by an epitaxial growth method using CVD, ALD, or molecular beam epitaxy (MBE). The epitaxial S/D features 240 are formed in contact with the channel epitaxial layers 216 and separated from the sacrificial epitaxial layers 214 by the first inner spacer layers 238 and the second inner spacer layers 239.

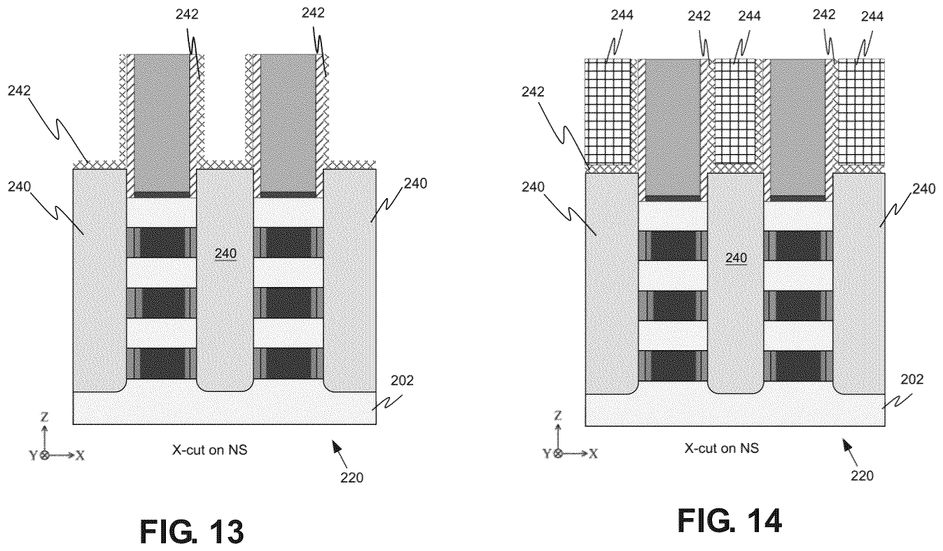

At block 124, the example method 100 includes forming a CESL layer. Referring to the example of FIG. 13, in an embodiment of block 124, a CESL layer 242 is formed over the S/D features 240. The CESL layer 242 may comprise silicon nitride, silicon oxynitride, silicon nitride with oxygen (O) or carbon (C) elements, and/or other materials; and may be formed by CVD, PVD (physical vapor deposition), ALD, or other suitable methods. In various embodiments, the CESL layer 242 is formed from SiN.

At block 126, the example method 100 includes forming an ILD layer. Referring to the example of FIG. 14, in an embodiment of block 126, an interlayer dielectric (ILD) layer 244 is formed over the CESL layer 242. The ILD layer 244 may comprise tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 244 may be formed by PECVD, flowable CVD (FCVD), or other suitable methods. In some embodiments, forming the ILD layer 244 further includes performing a CMP process to planarize a top surface of the device 200, such that the top surfaces of the sacrificial gate structure 224 are exposed.

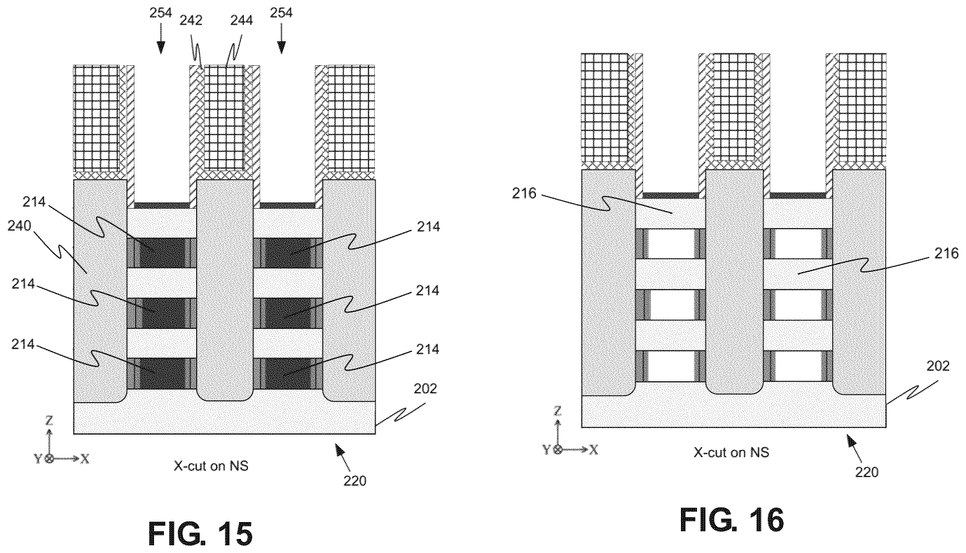

At block 128, the example method 100 includes removing the dummy gate stack to form a gate trench. Referring to the example of FIG. 15, in an embodiment of block 128, the sacrificial gate structure 224 has been removed to form a gate trench 254. The gate trench 254 exposes the fin 220 in the channel region(s). The ILD layer 244 and the CESL layer 242 protects the epitaxial S/D features 240 during the removal of the sacrificial gate structure 224. The sacrificial gate structure 224 can be removed using plasma dry etching and/or wet etching. When the sacrificial gate electrode layer is polysilicon and the ILD layer 244 is an oxide, a wet etchant such as a TMAH solution can be used to selectively remove the sacrificial gate electrode layer. The sacrificial gate dielectric layer is thereafter removed using plasma dry etching and/or wet etching.

At block 130, the example method 100 includes removing the sacrificial epitaxial layers to form nanosheets. The first inner spacer layers 238 can protect the second inner spacer layers 239 during the removal of the sacrificial epitaxial layers 214. Referring to the example of FIG. 16, in an embodiment of block 130, sacrificial epitaxial layers 214 have been removed thereby releasing channel members from the channel region of the GAA device. In the illustrated embodiment, channel members are channel epitaxial layers 216 in the form of nanosheets. In various embodiments, the channel epitaxial layers 216 include silicon, and the sacrificial epitaxial layers 214 include silicon germanium. In various embodiments, the plurality of sacrificial epitaxial layers 214 were selectively removed via a selective removal process that included oxidizing the plurality of sacrificial epitaxial layers 214 using a suitable oxidizer, such as ozone. Thereafter, the oxidized sacrificial epitaxial layers 214 were selectively removed via a dry etching process, for example, by applying an HCl gas at a temperature of about 500 degrees Celsius to about 700 degrees Celsius, or applying a gas mixture of CF₄, SF₆, and CHF₃.

The material type of the first inner spacer layers 238 is more resistant to the selective removal process than the material type of the second inner spacer layers 239. By having the first inner spacer layers 238 next to the sacrificial epitaxial layers 214 and shielding the second inner spacer layers 239 from the sacrificial epitaxial layers 214, unacceptable inner spacer loss during the sacrificial epitaxial layer removal process can be avoided.

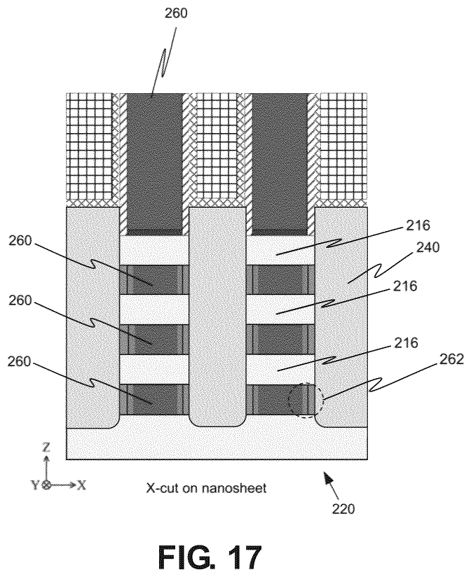

At block 132, the example method 100 includes forming high-K metal gate structures. Referring to the example of FIG. 17, in an embodiment of block 132, a gate structure 260 is formed. In various embodiments, the gate structure 260 is the gate of a multi-gate transistor. In various embodiments, the gate structure 260 is a high-K metal gate stack, however other compositions are possible. In various embodiments the high-K metal gate stack includes a gate dielectric layer that includes an interfacial layer and a high-k dielectric layer. The high-k dielectric layer wraps each of the nanosheets 216, and the interfacial layer is interposed between the high-k dielectric layer and the nanosheets 216. The interfacial layer may include a dielectric material such as silicon oxide (SiO₂) or silicon oxynitride (SiON), and may be formed by chemical oxidation, thermal oxidation, atomic layer deposition (ALD), CVD, and/or other suitable methods. The high-k dielectric layer may include hafnium oxide (HfO₂), hafnium silicon oxide (HfSiO), hafnium silicon oxynitride (HfSiON), hafnium tantalum oxide (HMO), hafnium titanium oxide (HfTiO), hafnium zirconium oxide (HfZrO), other suitable high-k dielectric materials, and/or combinations thereof. The high-k material may further be selected from metal oxides, metal nitrides, metal silicates, transition metal-oxides, transition metal-nitrides, transition metal-silicates, oxynitrides of metals, metal aluminates, zirconium silicate, zirconium aluminate, silicon oxide, silicon nitride, silicon oxynitride, zirconium oxide, titanium oxide, aluminum oxide, hafnium dioxide-alumina (HfO₂—Al₂O₃) alloy, other suitable materials, and/or combinations thereof. The high-k dielectric layer may be formed by any suitable process, such as atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, other suitable processes, and/or combinations thereof. In one embodiment, the gate dielectric layer is formed using a highly conformal deposition process such as ALD in order to ensure the formation of a gate dielectric layer having a uniform thickness around each channel layers. The high-K metal gate structures may include additional material layers.

At block 134, the example method 100 includes performing further fabrication. A semiconductor device may undergo further processing to form various features and regions known in the art. For example, subsequent processing may form contact openings, contact metal, as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 100, and some process steps described above may be replaced or eliminated in accordance with various embodiments of the method 100.

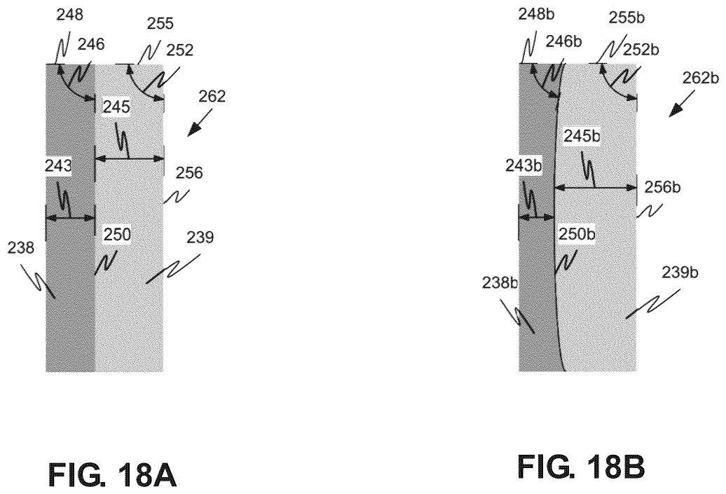

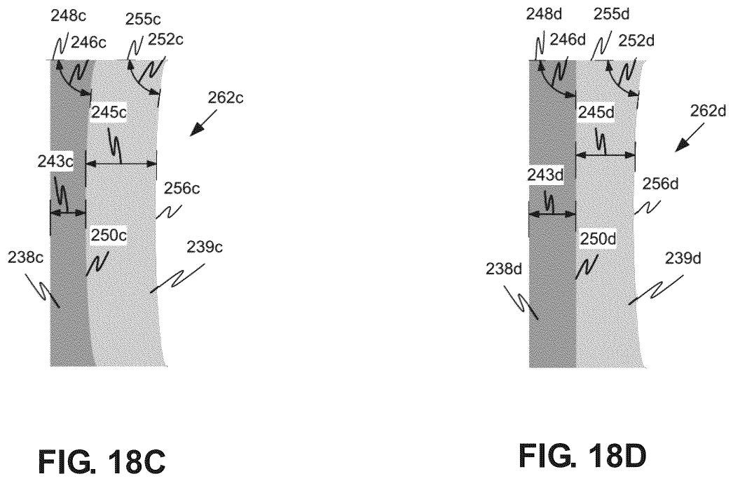

FIG. 18A is a diagram depicting an example double inner spacer layer 262. The example double inner spacer layer 262 includes a first inner spacer layer 238 and a second inner spacer layer 239. In various embodiments, the first inner spacer layers 238 comprise SiB and the boron doping concentration of the first inner spacer layers 238 is about 5×10²⁰ to about 1×10²² parts per cm³. In various embodiments, the boron doping concentration of the first inner spacer layers 238 is about 1% to about 20%. In various embodiments, this concentration of boron is sufficient to allow the first inner spacer layers 238 to protect the second inner spacer layers 239 from spacer loss during the replacing of the sacrificial epitaxial layer 214 with the metal gate structure 260 without impacting the benefits of the second inner spacer layers 239 in protecting against source/drain damage. The protection against spacer loss can prevent source/drain damage.

In various embodiments, the second inner spacer layers 239 comprise SiOCN and the carbon concentration of the second inner spacer layers 239 is about 1×10¹⁹ to about 1×10²¹ parts per cm³. In various embodiments, the carbon concentration of the second inner spacer layers 239 is about 0.02% to about 2%. In various embodiments, this concentration of carbon is high enough for the second inner spacer layers 239 to be protective, but not too high to impact device yield.

In various embodiments, the second inner spacer layers 239 comprise SiOCN and the nitride concentration of the second inner spacer layers 239 is about 1×10¹⁹ to about 5×10²¹ parts per cm³. In various embodiments, the nitride concentration of the second inner spacer layers 239 is about 0.02% to about 10%. In various embodiments, this concentration of nitrogen is high enough for the second inner spacer layers 239 to be protective, but not too high to impact device yield.

In various embodiments, the second inner spacer layers 239 comprise SiOCN and the oxide concentration of the second inner spacer layers 239 is about 1×10¹⁹ to about 5×10²¹ parts per cm³. In various embodiments, the oxide concentration of the second inner spacer layers 239 is about 0.02% to about 10%. In various embodiments, this concentration of oxide is high enough for the second inner spacer layers 239 to be protective, but not too high to impact device yield.

In various embodiments, the thickness 243 of the first inner spacer layers 238 is about 0.5 nm to about 3 nm. In various embodiments, the thickness 245 of the second inner spacer layers 239 is about 2 nm to about 4.5 nm. In various embodiments, the combined thickness 243 and thickness 245 is about 5 nm. In various embodiments, the ratio of the thickness 245 of the second inner spacer layers 239 to the thickness 243 of the first inner spacer layers 238 is in the range of about 9:1 to about 2:3. In various embodiments, this range of thickness 243 is sufficient for the first inner spacer layers 238 to protect against spacer loss without impacting device yield. In various embodiments, this range of thickness 245 is sufficient to protect against source/drain damage without impacting device yield.

The first inner spacer layers 238 have an outer angle 246 between a top surface 248 of the first inner spacer layers 238 and a sidewall 250 of the first inner spacer layers 238 that faces an adjacent S/D feature 240. The second inner spacer layers 239 has an outer angle 252 between a top surface 255 of the second inner spacer layers 239 and a sidewall 256 of the second inner spacer layers 239 that faces the adjacent S/D feature 240. In various embodiments, the outer angle 246 of the first inner spacer layers 238 has a magnitude that is between about 60° to about 90°. In various embodiments, the outer angle 252 of the second inner spacer layers 239 has a magnitude that is between about 60° to about 90°.

In various embodiments, an outer angle 246 of about 60° or more is large enough for the first inner spacer layers 238 to have sufficient structure to protect the second inner spacer layers 239 from spacer loss during the replacing of the sacrificial epitaxial layer 214 with the metal gate structure 260. The protection against spacer loss can prevent source/drain damage.

FIGS. 18B, 18C, and 18D are diagrams depicting additional embodiments of the double inner spacer layer 262. After formation of the first inner spacer layers 238, an outer sidewall 250 of the first inner spacer layers 238 that faces an adjacent S/D feature 240 may not have a straight, vertical shape as depicted in FIG. 18A, but instead might have a bow shape as depicted in FIGS. 18C and 18D. Similarly, after formation of the second inner spacer layers 239, an outer sidewall 256 of the second inner spacer layers 239 that faces an adjacent S/D feature 240 may not have a straight, vertical shape as depicted in FIG. 18A, but instead have a bow shape as depicted in FIGS. 18B and 18C.

FIG. 18B is a diagram depicting an example double inner spacer layer 262b. The example double inner spacer layer 262b includes a first inner spacer layer 238b and a second inner spacer layer 239b. In various embodiments, the first inner spacer layers 238b comprise SiB and the boron doping concentration of the first inner spacer layers 238b is about 5×10²⁰ to about 1×10²² parts per cm³. In various embodiments, the boron doping concentration of the first inner spacer layers 238b is about 1% to about 20%. In various embodiments, this concentration of boron is sufficient to allow the first inner spacer layers 238b to protect the second inner spacer layers 239b from spacer loss during the replacing of the sacrificial epitaxial layer 214 with the metal gate structure 260 without impacting the benefits of the second inner spacer layers 239b in protecting against source/drain damage. The protection against spacer loss can prevent source/drain damage.

In various embodiments, the second inner spacer layers 239b comprise SiOCN and the carbon concentration of the second inner spacer layers 239b is about 1×10¹⁹ to about 1×10²¹ parts per cm³. In various embodiments, the carbon concentration of the second inner spacer layers 239b is about 0.02% to about 2%. In various embodiments, this concentration of carbon is high enough for the second inner spacer layers 239b to be protective, but not too high to impact device yield.

In various embodiments, the second inner spacer layers 239b comprise SiOCN and the nitride concentration of the second inner spacer layers 239b is about 1×10¹⁹ to about 5×10²¹ parts per cm³. In various embodiments, the nitride concentration of the second inner spacer layers 239b is about 0.02% to about 10%. In various embodiments, this concentration of nitrogen is high enough for the second inner spacer layers 239b to be protective, but not too high to impact device yield.

In various embodiments, the second inner spacer layers 239b comprise SiOCN and the oxide concentration of the second inner spacer layers 239b is about 1×10¹⁹ to about 5×10²¹ parts per cm³. In various embodiments, the oxide concentration of the second inner spacer layers 239b is about 0.02% to about 10%. In various embodiments, this concentration of oxide is high enough for the second inner spacer layers 239b to be protective, but not too high to impact device yield.

In various embodiments, the thickness 243b of the first inner spacer layers 238b is about 0.5 nm to about 3 nm. In various embodiments, the thickness 245b of the second inner spacer layers 239b is about 2 nm to about 4.5 nm. In various embodiments, the combined thickness 243b and thickness 245b is about 5 nm. In various embodiments, the ratio of the thickness 245b of the second inner spacer layers 239b to the thickness 243b of the first inner spacer layers 238b is in the range of about 9:1 to about 2:3. In various embodiments, this range of thickness 243b is sufficient for the first inner spacer layers 238b to protect against spacer loss without impacting device yield. In various embodiments, this range of thickness 245b is sufficient to protect against source/drain damage without impacting device yield.

The first inner spacer layers 238b have an outer angle 246b between a top surface 248b of the first inner spacer layers 238b and a sidewall 250b of the first inner spacer layers 238b that faces an adjacent S/D feature 240. The second inner spacer layers 239b has an outer angle 252b between a top surface 255b of the second inner spacer layers 239b and a sidewall 256b of the second inner spacer layers 239b that faces the adjacent S/D feature 240. In various embodiments, the outer angle 246b of the first inner spacer layers 23b8 has a magnitude that is between about 60° to about 90°. The outer angle 246b is measured between the top surface 248b and a tangent line of the sidewall 250b extending from the top surface 248b. In various embodiments, the outer angle 252b of the second inner spacer layers 239b has a magnitude that is between about 60° to about 90°. The outer angle 252b is measured between the top surface 248b and a tangent line of the sidewall 256b extending from the top surface 248b.

In various embodiments, an outer angle 246b of about 60° or more is large enough for the first inner spacer layers 238b to have sufficient structure to protect the second inner spacer layers 239b from spacer loss during the replacing of the sacrificial epitaxial layer 214 with the metal gate structure 260. The protection against spacer loss can prevent source/drain damage.

FIG. 18C is a diagram depicting an example double inner spacer layer 262c. The example double inner spacer layer 262c includes a first inner spacer layer 238c and a second inner spacer layer 239c. In various embodiments, the first inner spacer layers 238c comprise SiB and the boron doping concentration of the first inner spacer layers 238c is about 5×10²⁰ to about 1×10²² parts per cm³. In various embodiments, the boron doping concentration of the first inner spacer layers 238c is about 1% to about 20%. In various embodiments, this concentration of boron is sufficient to allow the first inner spacer layers 238c to protect the second inner spacer layers 239c from spacer loss during the replacing of the sacrificial epitaxial layer 214 with the metal gate structure 260 without impacting the benefits of the second inner spacer layers 239c in protecting against source/drain damage. The protection against spacer loss can prevent source/drain damage.

In various embodiments, the second inner spacer layers 239c comprise SiOCN and the carbon concentration of the second inner spacer layers 239c is about 1×10¹⁹ to about 1×10²¹ parts per cm³. In various embodiments, the carbon concentration of the second inner spacer layers 239c is about 0.02% to about 2%. In various embodiments, this concentration of carbon is high enough for the second inner spacer layers 239c to be protective, but not too high to impact device yield.

In various embodiments, the second inner spacer layers 239c comprise SiOCN and the nitride concentration of the second inner spacer layers 239c is about 1×10¹⁹ to about 5×10²¹ parts per cm³. In various embodiments, the nitride concentration of the second inner spacer layers 239c is about 0.02% to about 10%. In various embodiments, this concentration of nitrogen is high enough for the second inner spacer layers 239c to be protective, but not too high to impact device yield.

In various embodiments, the second inner spacer layers 239c comprise SiOCN and the oxide concentration of the second inner spacer layers 239c is about 1×10¹⁹ to about 5×10²¹ parts per cm³. In various embodiments, the oxide concentration of the second inner spacer layers 239c is about 0.02% to about 10%. In various embodiments, this concentration of oxide is high enough for the second inner spacer layers 239c to be protective, but not too high to impact device yield.

In various embodiments, the thickness 243c of the first inner spacer layers 238c is about 0.5 nm to about 3 nm. In various embodiments, the thickness 245c of the second inner spacer layers 239c is about 2 nm to about 4.5 nm. In various embodiments, the combined thickness 243c and thickness 245c is about 5 nm. In various embodiments, the ratio of the thickness 245c of the second inner spacer layers 239c to the thickness 243c of the first inner spacer layers 238c is in the range of about 9:1 to about 2:3. In various embodiments, this range of thickness 243c is sufficient for the first inner spacer layers 238c to protect against spacer loss without impacting device yield. In various embodiments, this range of thickness 245c is sufficient to protect against source/drain damage without impacting device yield.

The first inner spacer layers 238c have an outer angle 246c between a top surface 248c of the first inner spacer layers 238c and a sidewall 250c of the first inner spacer layers 238c that faces an adjacent S/D feature 240. The second inner spacer layers 239c has an outer angle 252c between a top surface 255c of the second inner spacer layers 239c and a sidewall 256c of the second inner spacer layers 239c that faces the adjacent S/D feature 240. In various embodiments, the outer angle 246c of the first inner spacer layers 23b8 has a magnitude that is between about 60° to about 90°. The outer angle 246c is measured between the top surface 248c and a tangent line of the sidewall 250c extending from the top surface 248c. In various embodiments, the outer angle 252c of the second inner spacer layers 239c has a magnitude that is between about 60° to about 90°. The outer angle 252c is measured between the top surface 248c and a tangent line of the sidewall 256c extending from the top surface 248c.

In various embodiments, an outer angle 246c of about 60° or more is large enough for the first inner spacer layers 238c to have sufficient structure to protect the second inner spacer layers 239c from spacer loss during the replacing of the sacrificial epitaxial layer 214 with the metal gate structure 260. The protection against spacer loss can prevent source/drain damage.

FIG. 18D is a diagram depicting an example double inner spacer layer 262d. The example double inner spacer layer 262d includes a first inner spacer layer 238d and a second inner spacer layer 239d. In various embodiments, the first inner spacer layers 238d comprise SiB and the boron doping concentration of the first inner spacer layers 238d is about 5×10²⁰ to about 1×10²² parts per cm³. In various embodiments, the boron doping concentration of the first inner spacer layers 238d is about 1% to about 20%. In various embodiments, this concentration of boron is sufficient to allow the first inner spacer layers 238d to protect the second inner spacer layers 239d from spacer loss during the replacing of the sacrificial epitaxial layer 214 with the metal gate structure 260 without impacting the benefits of the second inner spacer layers 239d in protecting against source/drain damage. The protection against spacer loss can prevent source/drain damage.

In various embodiments, the second inner spacer layers 239d comprise SiOCN and the carbon concentration of the second inner spacer layers 239d is about 1×10¹⁹ to about 1×10²¹ parts per cm³. In various embodiments, the carbon concentration of the second inner spacer layers 239d is about 0.02% to about 2%. In various embodiments, this concentration of carbon is high enough for the second inner spacer layers 239d to be protective, but not too high to impact device yield.

In various embodiments, the second inner spacer layers 239d comprise SiOCN and the nitride concentration of the second inner spacer layers 239d is about 1×10¹⁹ to about 5×10²¹ parts per cm³. In various embodiments, the nitride concentration of the second inner spacer layers 239d is about 0.02% to about 10%. In various embodiments, this concentration of nitrogen is high enough for the second inner spacer layers 239d to be protective, but not too high to impact device yield.

In various embodiments, the second inner spacer layers 239d comprise SiOCN and the oxide concentration of the second inner spacer layers 239d is about 1×10¹⁹ to about 5×10²¹ parts per cm³. In various embodiments, the oxide concentration of the second inner spacer layers 239d is about 0.02% to about 10%. In various embodiments, this concentration of oxide is high enough for the second inner spacer layers 239d to be protective, but not too high to impact device yield.

In various embodiments, the thickness 243d of the first inner spacer layers 238d is about 0.5 nm to about 3 nm. In various embodiments, the thickness 245d of the second inner spacer layers 239d is about 2 nm to about 4.5 nm. In various embodiments, the combined thickness 243d and thickness 245d is about 5 nm. In various embodiments, the ratio of the thickness 245d of the second inner spacer layers 239d to the thickness 243d of the first inner spacer layers 238d is in the range of about 9:1 to about 2:3. In various embodiments, this range of thickness 243d is sufficient for the first inner spacer layers 238d to protect against spacer loss without impacting device yield. In various embodiments, this range of thickness 245d is sufficient to protect against source/drain damage without impacting device yield.

The first inner spacer layers 238d have an outer angle 246d between a top surface 248d of the first inner spacer layers 238d and a sidewall 250d of the first inner spacer layers 238d that faces an adjacent S/D feature 240. The second inner spacer layers 239d has an outer angle 252d between a top surface 255d of the second inner spacer layers 239d and a sidewall 256d of the second inner spacer layers 239d that faces the adjacent S/D feature 240. In various embodiments, the outer angle 246d of the first inner spacer layers 23b8 has a magnitude that is between about 60° to about 90°. The outer angle 246d is measured between the top surface 248d and a tangent line of the sidewall 250d extending from the top surface 248d. In various embodiments, the outer angle 252d of the second inner spacer layers 239d has a magnitude that is between about 60° to about 90°. The outer angle 252d is measured between the top surface 248d and a tangent line of the sidewall 256d extending from the top surface 248d.

In various embodiments, an outer angle 246d of about 60° or more is large enough for the first inner spacer layers 238d to have sufficient structure to protect the second inner spacer layers 239d from spacer loss during the replacing of the sacrificial epitaxial layer 214 with the metal gate structure 260. The protection against spacer loss can prevent source/drain damage.

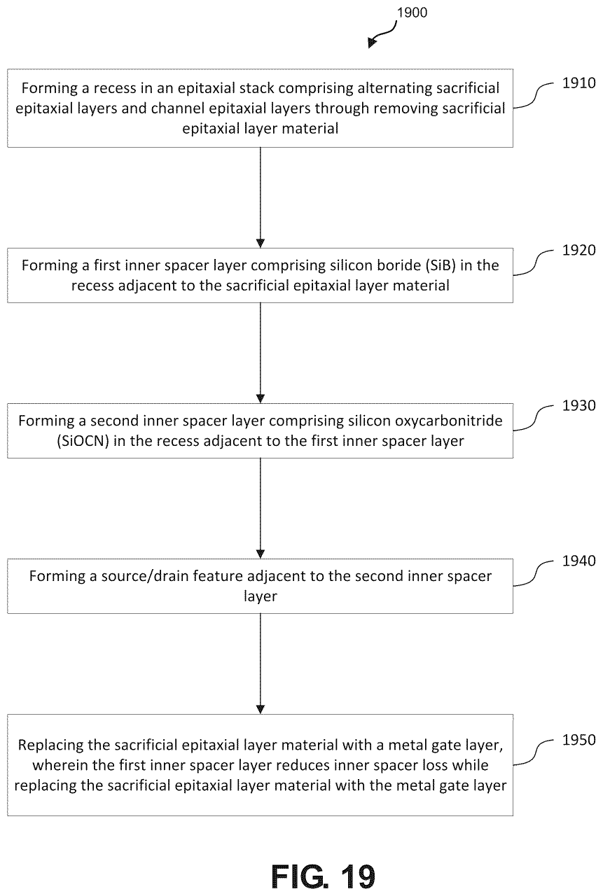

FIG. 19 is a flowchart of an example method 1900 for forming a double inner spacer layer in a transistor device, in accordance with some embodiments. The method 1900 is merely an example and is not intended to limit the present disclosure beyond what is explicitly recited in the claims. Additional steps may be provided before, during, and after method 1900. As with the other method embodiments discussed herein, it is understood that parts of the semiconductor devices that may be fabricated by semiconductor technology process flow, and thus some processes are only briefly described herein.

At block 1910, the example method 1900 includes forming a recess in an epitaxial stack comprising alternating sacrificial epitaxial layers and channel epitaxial layers through removing sacrificial epitaxial layer material. Referring to the example of FIG. 9, in an embodiment of block 1910, the sacrificial epitaxial layers 214 have been etched back forming sacrificial epitaxial layer recesses 235 bounded on the top and bottom by channel epitaxial layers 216 and laterally by the recessed sacrificial epitaxial layers 214. The sacrificial epitaxial layers 214 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. Alternatively, at block 1910 lateral ends of the sacrificial epitaxial layers 214 that are exposed in the recess 234 may be selectively oxidized to increase the etch selectivity between the epitaxial layers 214 and 216. In some examples, the oxidation process may be performed by exposing the device 200 to a wet oxidation process, a dry oxidation process, or a combination thereof.

At block 1920, the example method 1900 includes forming a first inner spacer layer comprising silicon boride (SiB) in the recess adjacent to the sacrificial epitaxial layer material. Referring to the example of FIG. 10, in an embodiment of block 1920, first inner spacer layers 238 are formed in the sacrificial epitaxial layer recesses 235. The first inner spacer layers 238 can be formed by ALD or any other suitable method.

At block 1930, the example method 1900 includes performing a wet clean of the first inner spacer layers. Performing a wet clean can remove oxide off of the surfaces of the first inner spacer layers.

At block 1940, the example method 1900 includes forming a second inner spacer layer comprising silicon oxycarbonitride (SiOCN) in the recess adjacent to the first inner spacer layer. Forming the second inner spacer layer may include depositing inner spacer material comprising SiOCN, and trimming the second inner spacer layer (e.g., via etching operations). Referring to the example of FIG. 11, in an embodiment of block 1930, second inner spacer layers 239 are formed in the sacrificial epitaxial layer recesses 235 adjacent to the first inner spacer layers 238. In some embodiments, the second inner spacer layers 239 are deposited as a conformal layer. The second inner spacer layers 239 can be formed by ALD or any other suitable method. After the second inner spacer layers 239 are formed, an etching operation may be performed to partially remove the second inner spacer layers 239.

At block 1950, the example method 1900 includes forming a source/drain feature adjacent to the second inner spacer layer. Referring to the example of FIG. 12, in an embodiment of block 1940, epitaxial S/D features 240 are formed in recess 234. In some embodiments, the epitaxial S/D features 240 include silicon for NFETs and SiGe for PFETs. In some embodiments, the epitaxial S/D features 240 are formed by an epitaxial growth method using CVD, ALD, or molecular beam epitaxy (MBE). The epitaxial S/D features 240 are formed in contact with the channel epitaxial layers 216 and separated from the sacrificial epitaxial layers 214 by the inner spacer layers 238, 239.

At block 1960, the example method 1900 includes replacing the sacrificial epitaxial layer material with a metal gate layer, wherein the first inner spacer layer reduces inner spacer loss while the sacrificial epitaxial layer material is replaced with the metal gate layer. Referring to the example of FIG. 17, in an embodiment of block 1950, a gate structure 260 is formed. In various embodiments, the gate structure 260 is the gate of a multi-gate transistor. In various embodiments, the gate structure 260 is a high-K metal gate stack.

In some aspects, the techniques described herein relate to a method, including: forming a first inner spacer layer of a first material type in a recess adjacent to sacrificial epitaxial layer material; forming a second inner spacer layer of a second material type in the recess adjacent to the first inner spacer layer; and replacing the sacrificial epitaxial layer material with a metal gate layer, wherein the first inner spacer layer reduces inner spacer loss while the sacrificial epitaxial layer material is replaced with the metal gate layer.

In some aspects, the techniques described herein relate to a method, wherein the first material type includes silicon boride (SiB) and the second material type includes silicon oxycarbonitride (SiOCN).

In some aspects, the techniques described herein relate to a method, wherein the first inner spacer layer has a boron doping concentration of about 1% to about 20%.

In some aspects, the techniques described herein relate to a method, wherein the second inner spacer layer has a carbon concentration of about 0.02% to about 2%.

In some aspects, the techniques described herein relate to a method, wherein the second inner spacer layer has a nitride concentration of about 0.02% to about 10%.

In some aspects, the techniques described herein relate to a method, the second inner spacer layer has an oxide concentration of about 0.02% to about 10%.

In some aspects, the techniques described herein relate to a method, wherein: the first inner spacer layer has a thickness of about 0.5 nm to about 3 nm; and the second inner spacer layer has a thickness of about 2 nm to about 4.5 nm.

In some aspects, the techniques described herein relate to a semiconductor structure, including: a metal gate structure of a multi-gate transistor; a source/drain feature; a first inner spacer layer of a first material type including silicon boride (SiB) disposed adjacent to the metal gate structure; and a second inner spacer layer of a second material type disposed between the first inner spacer layer and the source/drain feature.

In some aspects, the techniques described herein relate to a semiconductor structure, wherein the second material type includes silicon oxycarbonitride (SiOCN).

In some aspects, the techniques described herein relate to a semiconductor structure, wherein: the first inner spacer layer has a boron doping concentration of about 1% to about 20%; the second inner spacer layer has a carbon concentration of about 0.02% to about 2%; the second inner spacer layer has a nitride concentration of about 0.02% to about 10%; and the second inner spacer layer has an oxide concentration of about 0.02% to about 10%.

In some aspects, the techniques described herein relate to a semiconductor structure, wherein the first inner spacer layer has a thickness of about 0.5 nm to about 3 nm.

In some aspects, the techniques described herein relate to a semiconductor structure, wherein the second inner spacer layer has a thickness of about 2 nm to about 4.5 nm.

In some aspects, the techniques described herein relate to a semiconductor structure, wherein the first inner spacer layer has a first angle between a top surface of the first inner spacer layer and a sidewall of the first inner spacer layer that faces an adjacent source/drain feature, and the first angle of the first inner spacer layer has a magnitude that is between about 60 to about 90°.

In some aspects, the techniques described herein relate to a semiconductor structure, wherein the second inner spacer layer has an outer angle between a top surface of the second inner spacer layer and a sidewall of the second inner spacer layer that faces an adjacent source/drain feature, and the outer angle of the second inner spacer layer has a magnitude that is between about 60° to about 90°.

In some aspects, the techniques described herein relate to a method, including: forming a recess in an epitaxial stack including alternating sacrificial epitaxial layers and channel epitaxial layers through removing sacrificial epitaxial layer material; forming a first inner spacer layer including silicon boride (SiB) in the recess adjacent to the sacrificial epitaxial layer material; forming a second inner spacer layer including silicon oxycarbonitride (SiOCN) in the recess adjacent to the first inner spacer layer; forming a source/drain feature adjacent to the second inner spacer layer; and replacing the sacrificial epitaxial layer material with a metal gate layer, wherein the first inner spacer layer reduces inner spacer loss while the sacrificial epitaxial layer material is replaced with the metal gate layer.

In some aspects, the techniques described herein relate to a method, wherein the first inner spacer layer has a boron doping concentration of about 5×10²⁰ to about 1×10²² parts per cm³.

In some aspects, the techniques described herein relate to a method, wherein the second inner spacer layer has a carbon concentration of about 1×10¹⁹ to about 1×10²¹ parts per cm³.

In some aspects, the techniques described herein relate to a method, wherein the second inner spacer layer has a nitride concentration of about 1×10¹⁹ to about 5×10²¹ parts per cm³.

In some aspects, the techniques described herein relate to a method, the second inner spacer layer has a oxide concentration of about 1×10¹⁹ to about 5×10²¹ parts per cm³.

In some aspects, the techniques described herein relate to a method, wherein a ratio of thickness of the first inner spacer layer to the second inner spacer layer is about 1:9 to about 3:2.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A method, comprising:
forming a first inner spacer layer of a first material type in a recess adjacent to sacrificial epitaxial layer material;
forming a second inner spacer layer of a second material type in the recess adjacent to the first inner spacer layer; and
replacing the sacrificial epitaxial layer material with a metal gate layer, wherein the first inner spacer layer reduces inner spacer loss while the sacrificial epitaxial layer material is replaced with the metal gate layer.

2. The method of claim 1, wherein the first material type comprises silicon boride (SiB) and the second material type comprises silicon oxycarbonitride (SiOCN).

3. The method of claim 2, wherein the first inner spacer layer has a boron doping concentration of about 1% to about 20%.

4. The method of claim 2, wherein the second inner spacer layer has a carbon concentration of about 0.02% to about 2%.

5. The method of claim 2, wherein the second inner spacer layer has a nitride concentration of about 0.02% to about 10%.

6. The method of claim 2, the second inner spacer layer has an oxide concentration of about 0.02% to about 10%.

7. The method of claim 1, wherein:
the first inner spacer layer has a thickness of about 0.5 nm to about 3 nm; and
the second inner spacer layer has a thickness of about 2 nm to about 4.5 nm.

8. A semiconductor structure, comprising:
a metal gate structure of a multi-gate transistor;
a source/drain feature;
a first inner spacer layer of a first material type comprising silicon boride (SiB) disposed adjacent to the metal gate structure; and
a second inner spacer layer of a second material type disposed between the first inner spacer layer and the source/drain feature.

9. The semiconductor structure of claim 8, wherein the second material type comprises silicon oxycarbonitride (SiOCN).

10. The semiconductor structure of claim 9, wherein:
the first inner spacer layer has a boron doping concentration of about 1% to about 20%;
the second inner spacer layer has a carbon concentration of about 0.02% to about 2%;
the second inner spacer layer has a nitride concentration of about 0.02% to about 10%; and
the second inner spacer layer has an oxide concentration of about 0.02% to about 10%.

11. The semiconductor structure of claim 8, wherein the first inner spacer layer has a thickness of about 0.5 nm to about 3 nm.

12. The semiconductor structure of claim 8, wherein the second inner spacer layer has a thickness of about 2 nm to about 4.5 nm.

13. The semiconductor structure of claim 8, wherein the first inner spacer layer has a first angle between a top surface of the first inner spacer layer and a sidewall of the first inner spacer layer that faces an adjacent source/drain feature, and the first angle of the first inner spacer layer has a magnitude that is between about 60° to about 90°.

14. The semiconductor structure of claim 8, wherein the second inner spacer layer has an outer angle between a top surface of the second inner spacer layer and a sidewall of the second inner spacer layer that faces an adjacent source/drain feature, and the outer angle of the second inner spacer layer has a magnitude that is between about 60° to about 90°.

15. A method, comprising:
forming a recess in an epitaxial stack comprising alternating sacrificial epitaxial layers and channel epitaxial layers through removing sacrificial epitaxial layer material;
forming a first inner spacer layer comprising silicon boride (SiB) in the recess adjacent to the sacrificial epitaxial layer material using an etch gas that resists SiB from forming on the channel epitaxial layers;
performing a wet clean of the first inner spacer layer;
forming a second inner spacer layer comprising silicon oxycarbonitride (SiOCN) in the recess adjacent to the first inner spacer layer;
forming a source/drain feature adjacent to the second inner spacer layer; and
replacing the sacrificial epitaxial layer material with a metal gate layer, wherein the first inner spacer layer reduces inner spacer loss while the sacrificial epitaxial layer material is replaced with the metal gate layer.

16. The method of claim 15, wherein forming the first inner spacer layer comprises forming SiB in the recess using in-situ doping by B₂H₆ or BCl₃.

17. The method of claim 15, wherein forming the first inner spacer layer comprises forming SiB in the recess using SiH₂Cl₂ or SiH₄ or Si₂H₆ as a Si resource and B₂H₆ or BCl₃ as a B resource.

18. The method of claim 15, wherein the etch gas comprises HCl or Cl₂.

19. The method of claim 15, wherein forming the first inner spacer layer comprises forming SiB in the recess with a boron doping concentration of the first inner spacer layer of about 5×10²⁰ to about 1×10²² parts per cm³.

20. The method of claim 15, wherein forming the first inner spacer layer and forming the second inner spacer layer comprises forming the first inner spacer layer and forming the second inner spacer layer with a ratio of thickness of the first inner spacer layer to the second inner spacer layer of about 1:9 to about 3:2.
